(19) United States
(12) Patent Application Publication
(10) Pub. No.: US 2012/0007144 A1
(43) Pub. Date: Jan. 12, 2012

(54) Compound Semiconductor Device and Method of Producing the Same

(75) Inventors: Maurice Howard Fisher, Wiltshire (GB); Benoit Alfred Louis Roumiguires, Cardiff (GB); Aled Owen Morgan, Cardiff (GB)

(73) Assignee: IQE SILICON COMPOUNDS LTD, Cardiff (GB)

(21) Appl. No.: 13/154,174

(22) Filed: Jun. 6, 2011

Related U.S. Application Data
(63) Continuation of application No. 10/597,809, filed on Mar. 27, 2007, now abandoned.

(51) Int. Cl. H01L 29/06; H01L 21/20

(52) U.S. Cl. 257/191; 438/478; 257/E29.005; 257/E21.09

(57) ABSTRACT

A semiconductor device comprises an Si substrate 10 and a compound layer 11 of Si1-XGeX disposed on the substrate 10. X is varied from 0 to 0.2 away from the substrate 10 towards the upper surface of the compound layer 11, with the rate of change of X increasing through the layer.

The increasing rate of change of X significantly improves the defectivity levels and the surface roughness at the surface of layer 11.

This invention relates to a compound semiconductor device and to a method of producing such a device.

Silicon (Si) is widely used in the manufacture of semiconductor devices, since it is readily available commercially and exhibits a number of desirable characteristics. However, with increasing demands on the speed of semiconductors, it has become desirable to form semiconductor devices from materials such as germanium (Ge), which has a larger crystalline lattice constant and which therefore can operate at higher speeds.

Unfortunately, materials such as germanium are not readily available commercially and do not possess the desirable characteristics of silicon.

In order to overcome this problem, it is well known that the electron mobility of silicon can be increased by depositing silicon onto a silicon germanium compound of say Si0.8Ge0.2 to form a strained layer of silicon having an increased lattice constant towards that of the germanium constituent of the underlying compound.

A disadvantage of depositing a SiGe compound on a silicon semiconductor substrate is that dislocations will occur between the different materials owing their different lattice constants. In order to overcome this problem it is well known to deposit a graded compound of Si1-XGeX on the silicon substrate, where X is gradually varied from 0 to 0.2 over 5 to 6 μm through the layer.

A disadvantage of such graded compounds is that the defectivity and surface roughness of the final compound material is poor, with the result that these undesirable characteristics are carried through to any layers deposited on the final compound material.

We have now devised a semiconductor device which alleviates the above-mentioned problems.

In accordance with this invention, there is provided a semiconductor device comprising a substrate of a first semiconductor material and a compound layer of said first semiconductor material and a second semiconductor material disposed on the substrate, the ratio of the first material to the second material of the compound layer being decreased away from the substrate towards the upper surface of the compound layer, wherein the rate of decrease of the ratio varies within said layer.

We have found that varying the rate of decrease of the ratio of the first material to the second material surprisingly significantly reduces the surface roughness and defectivity levels at the surface of the compound layer.

Preferably the rate of decrease of the ratio increases away from the substrate towards the surface of the compound layer.

In one embodiment, the rate of decrease of the ratio varies linearly on opposite sides of an intermediate point within said layer at which the rate varies.

In an alternative embodiment, the rate of decrease of the ratio varies non-linearly within said layer.

It is also contemplated that the ratio may remain constant or increase between points intermediate said layer.

Preferably a final layer comprising said first material is deposited on the surface of the compound layer.

Preferably the first material is silicon and preferably, the second material is germanium.

Preferably the composition of the compound layer at the upper surface thereof comprises 10-50% of said second material.

Preferably the composition of the compound layer at the upper surface thereof comprises substantially 20% of said second material.

Also in accordance with this invention, there is provided a method of manufacturing a semiconductor device, the method comprising providing a substrate of a first semiconductor material depositing a compound layer of said first semiconductor material and a second semiconductor material on the substrate such that the ratio of the first material to the second material of the compound layer decreases away from the substrate towards the upper surface of the compound layer, the rate of decrease of the ratio being varied within the layer.

Preferably the rate of decrease of the ratio is increased from the substrate towards the surface of the compound layer.

In one embodiment, the rate of decrease of the ratio is varied linearly on opposite sides of an intermediate point within said layer where the rate is varied.

In an alternative embodiment, the rate of decrease of the ratio is varied non-linearly within the layer.

The compound layer is grown in a chamber into which materials comprising silicon and germanium are introduced. Typically, graded compound layers are formed by varying the respective amounts of silicon and germanium materials which are introduced into the chamber. However, in the present invention, the ratio of the first material to the second material of the compound layer is preferably decreased in part by decreasing the temperature at which the layer is deposited from the substrate towards the surface of the compound layer.

An embodiment of this invention will now be described by way of examples only and with reference to the accompanying drawings, in which:

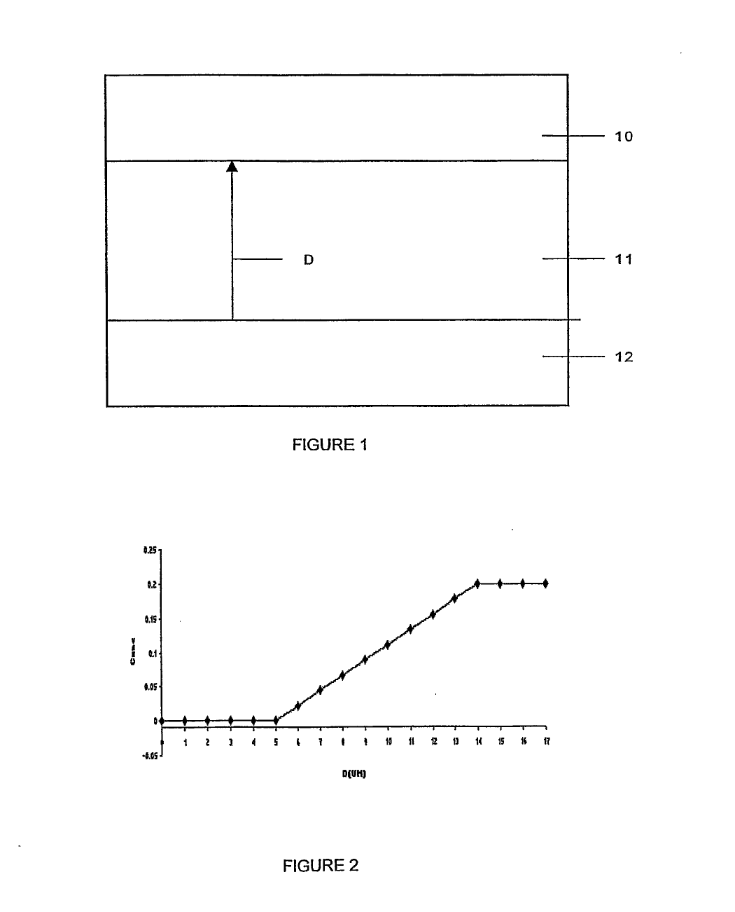

FIG. 1 is a schematic sectional view through a semiconductor device:

FIG. 2 is a graph showing X in Si1-XGeX at various points along a vertical line D extending through a graded layer of the semiconductor device FIG. 1, when formed in accordance with the prior art:

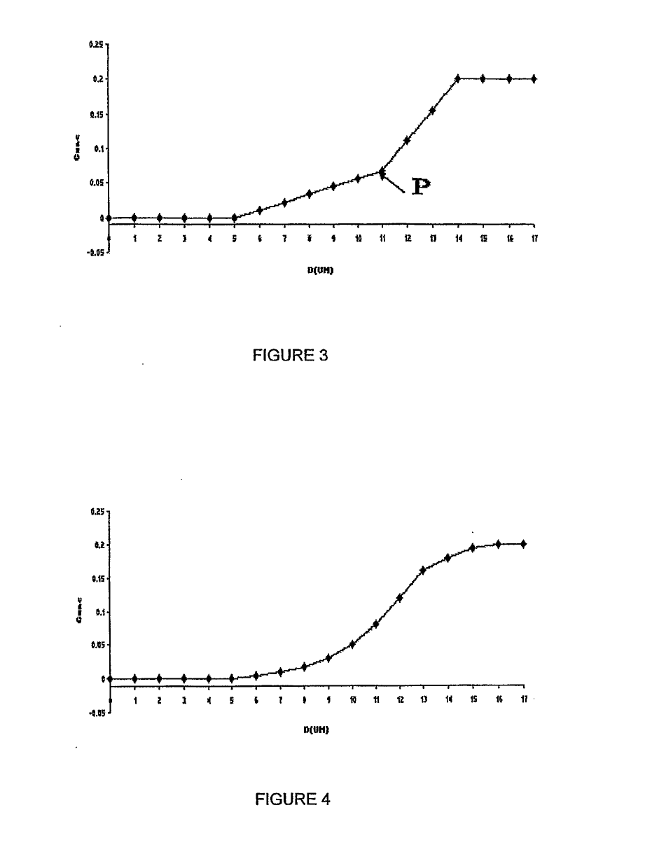

FIG. 3 is a similar graph of the semiconductor device of FIG. 1, when formed in accordance with an embodiment of this invention; and

FIG. 4 is a similar graph of the semiconductor device of FIG. 1, when formed in accordance with an alternative embodiment of this invention.

Referring to FIG. 1 of the drawings, there is shown a semiconductor device comprising a silicon substrate 10, a graded compound layer 11 of Si1-XGeX disposed on the substrate 10 and a capping layer 12 of silicon.

Semiconductor devices of the above-mentioned construction are well known. Hitherto the graded layer 11 has been formed by increasing X in Si1-XGeX linearly from 0 at the surface of the substrate 10 to about 0.2 at the surface of the graded layer 11. This gradual change in X reduces crystalline dislocations of the type which would occur if Si0.8Ge0.2 were deposited directly onto the silicon substrate 10.

The capping layer 12 of silicon adopts the larger lattice constant of the underlying Si0.8Ge0.2 and in this manner, the silicon layer 12 has a greater electron mobility than that of a conventional silicon layer.

A disadvantage of the above-mentioned arrangement is that there is always some inherent defectivity in the graded layer 11 caused by the change in lattice constant as X increases through the layer. This also has the effect of adversely affecting the surface roughness of the layer 11. These undesirable characteristics are carried through to the silicon capping layer 12.

Referring to FIG. 3 of the drawings, in accordance with this invention, the ratio of silicon to germanium in the graded layer 11 is gradually decreased in a linear manner until a point P is reached intermediate the layer, whereupon the linear rate of decrease of the ratio is increased until X reaches approximately 0.2.

We have found that this variation in the rate of change X through the layer 11 significantly improves the defectivity levels and the surface roughness at the surface of layer 11.

Referring to FIG. 4 of the drawings, in an alternative embodiment, the rate of change of X may vary through the layer in a non-linear manner. However, it is preferred that the rate of change of X increases away from the surface of the substrate 10.

A graded layer in accordance with this invention can be produced by initially introducing materials comprising silicon and germanium into a chamber at a starting growth temperature. In addition to adjusting the levels of materials fed into the chamber, the temperature is decreased to partially vary the germanium content X.

What is claimed:

1. A semiconductor device comprising a substrate of a first semiconductor material and a compound layer of said first semiconductor material and a second semiconductor material disposed on the substrate, the ratio of the first material to the second material of the compound layer being decreased away from the substrate towards the upper surface of the compound layer, wherein the rate of decrease of the ratio is linear and different on opposite sides of an intermediate point, and wherein the ratio is decreasing on opposite sides of the intermediate point, and wherein the ratio of the first material to the second material of the compound layer decreases from the intermediate point to the upper surface of the compound layer.

2. A semiconductor device as claimed in claim 1, in which the rate of decrease of the ratio increases away from the substrate towards the surface of the compound layer.

3-6. (canceled)

7. A semiconductor device as claimed in claim 1, in which a final layer comprising said first material is deposited on the surface of the compound layer.

8. A semiconductor device as claimed in claim 1, in which the first material is silicon.

9. A semiconductor device as claimed in claim 1, in which the second material is germanium.

10. A semiconductor device as claimed in claim 1, in which a composition of the compound layer at the upper surface thereof comprises 10-50% of said second material.

11. A semiconductor device as claimed in claim 10, in which the composition of the compound layer at the upper surface thereof comprises substantially 20% of said second material.

12. (canceled)

13. A method of manufacturing a semiconductor device, the method comprising providing a substrate of a first semiconductor material, depositing a compound layer of said first semiconductor material and a second semiconductor material on the substrate such that the ratio of the first material to the second material of the compound layer decreases away from the substrate towards the upper surface of the compound layer, the rate of decrease of the ratio being linear and different on opposite sides of an intermediate point, and wherein the ratio is decreasing on opposite sides of the intermediate point, and wherein the ratio of the first material to the second material of the compound layer decreases from the intermediate point to the upper surface of the compound layer.

14. A method as claimed in claim 13, in which the rate of decrease of the ratio is increased away from the substrate towards the surface of the compound layer.

15-16. (canceled)

17. A method as claimed in claim 13, in which the ratio of the first material to the second material of the compound layer is decreased in part by decreasing a temperature at which the layer is deposited from the substrate towards the surface of the compound layer.

18. (canceled)
